(19) United States
(12) Patent Application Publication
(10) Pub. No.: US 2006/0156981 A1
(43) Pub. Date: Jul. 20, 2006

(54) Wafer support pin assembly

(76) Inventors: Kyle Fondurulia, Phoenix, AZ (US); Carl White, Gilbert, AZ (US)

Correspondence Address: KNOBBE MARTENS OLSON & BEAR LLP, 2040 MAIN STREET, FOURTEENTH FLOOR, IRVINE, CA, 92614, US

(21) Appl. No.: 11/334,339

(22) Filed: Jan. 17, 2006

Related U.S. Application Data
(60) Provisional application No. 60/645,581, filed on Jan. 18, 2005.
(60) Provisional application No. 60/656,832, filed on Feb. 24, 2005.

(51) Int. Cl. H01L 21/44; C23C 16/00

(52) U.S. Cl. 118/715; 438/680

(57) ABSTRACT

A semiconductor wafer support pin assembly. A susceptor has at least three support pins configured to raise a wafer above the top surface of the susceptor. Each support pin includes and upper pin and a lower pin, which lock together by means of a quick-release mechanism in the form of a bayonet mount. The upper pin is made of a non-metallic material, such as polybenzimidazole. The susceptor is driven up and down by a lifting mechanism, driven by an electric motor or pneumatic cylinder. The susceptor moves up and down, relative to the support pins.

### REFERENCE TO RELATED APPLICATIONS

This application claims priority to U.S. Provisional Application No. 60/645,581, filed Jan. 18, 2005, and U.S. Provisional Application No. 60/656,832, filed Feb. 24, 2005.

### BACKGROUND OF THE INVENTION

1. Field of the Invention

The field of the invention relates generally to semiconductor fabrication, and more particularly to a semiconductor substrate holder for processing semiconductor substrates.

2. Description of the Related Art

Semiconductor processing steps typically employ various processing tools. Such processing tools include deposition devices, photolithography devices, polishing devices, etc. Most, if not all, of these devices use what is known as a substrate holding mechanism to hold a semiconductor substrate for processing. Some substrate holders or supports have a plurality (preferably at least three) of support pins that extend axially upward from a top surface of the substrate holder. The support pins can be stationary for use during processing or can be lift pins configured to lift or lower a semiconductor substrate from or onto the top surface of the substrate holder. The top surfaces of the support pins are configured to contact a lower or bottom surface (backside) of the semiconductor substrate. Processing (e.g., deposition, polishing, etc.) is typically performed on the top or upper surface of the semiconductor substrate.

Many semiconductor processing devices are single-wafer processing type devices having a substrate support within a reaction chamber. Processing of a substrate or wafer is typically performed while heating the substrate on the substrate support or susceptor. A typical susceptor in a single-wafer processing type device comprises a disk-shaped body formed of metal or ceramic having high heat conductivity, and may also have a built-in heating element, such as an electric heater, within the susceptor.

Certain areas of the backside of the substrate may be subject to particle contamination during and/or after one or more processing steps. Such contamination may lead to or cause defects in the substrate. Particles can also contaminate the processing environment within the reaction chamber, which can, in turn, contaminate a substrate being processed in the chamber.

Particles are sometimes generated when the substrate support is assembled. For example, substrate supports having support pins typically require hand tools (e.g., wrench) for assembly, which increase particle generation. The materials used in support pin assembly can cause also galling of the pin and guide, which also increases particles. Often, there is a threaded interface between the pin head and the body of the support pin. Such a threaded design typically requires vacuum vent holes to releasing undesirable trapped gas in the threaded connection between the pin head and the body of the pin due to a rise in process pressure. These vent holes, unfortunately, are potential particle and contamination traps. Furthermore, pin heads made of metal are undesirable because the metal can release metallic contaminants, which are undesirable in semiconductor processing. Some support pins are formed of titanium, which may require an alumina passivation layer over the titanium pins to protect titanium and to create a passive surface for substrate.

Substrate supports are used in deposition chambers, such as chemical vapor deposition (CVD) and atomic layer deposition (ALD) chambers. ALD processes provide the benefit of a conformal deposition layer. However, there are particular problems with ALD processes, such as the need for sequential self-saturating pulses. In ALD processes, it is important to separate reactants in time and space to avoid CVD-like reactions, which destroy the conformality benefits of ALD. For example, in ALD processes, trapped gas from one pulse can leak or diffuse from its trap and react with another pulse, creating particles and non-uniformity from CVD-like reactions.

The needs for tools, as discussed above, as well as the selection of materials for parts of the substrate support, add to the complexity of manufacturing and assembling substrate supports.

### SUMMARY OF THE INVENTION

According to an aspect of the invention, a substrate support is provided for processing semiconductor substrates. The substrate support has a plurality of openings extending from a top surface to a bottom surface. The substrate support includes a plurality of support pins. Each of the plurality of support pins is slidably mounted in one of the plurality of openings. Each of the plurality of support pins includes an upper pin and a lower pin. The upper pin is engaged with the lower pin by means of a bayonet mount.

According to another aspect of the invention, a method is provided for assembling a semiconductor substrate support having a plurality of support structures. A susceptor having a plurality of bores extending therethrough from a top surface to a bottom surface is provided. An upper pin is passed through each of the plurality of bores, and each of the upper pins is engaged to a lower pin below the upper pin by rotating one of the upper pin and the lower pin by less than about 360 degrees.

According to yet another aspect of the invention, a process tool for processing semiconductor substrate is provided. The process tool comprises a susceptor, a lifting mechanism, and a heater. The susceptor has a plurality of openings extending from a top surface to a bottom surface. The susceptor comprises a plurality of support pins, wherein each of the plurality of support pins is slidably mounted in one of the plurality of openings, each of the plurality of support pins comprising an upper pin and a lower pin, wherein the upper pin is engaged with the lower pin by means of a quick-release mechanism. The lifting mechanism is configured to raise or lower the susceptor. The substrate support is mounted over the heater.

According to another aspect of the invention, a wafer support pin configured for slidably mounting in an opening in a wafer support for semiconductor processing is provided. The support pin comprises an upper pin having an enlarged pin head and an upper pin shaft extending downwardly from the pin head. A lower pin is configured to engage with the upper pin by means of a bayonet mount.

### BRIEF DESCRIPTION OF THE DRAWINGS

These and other aspects of the invention will be readily apparent from the following description and from the appended drawings (not to scale), which are meant to illustrate and not to limit the invention, and wherein:

FIG. 1A is a perspective and partially cross-sectional view of an embodiment of a substrate support having a support pin.

FIG. 1B is an exploded, bottom perspective view of an embodiment of a substrate support having a support pin extending through a bore in the support.

FIG. 1C is a cross-sectional side view of a support pin in a lowered position in a substrate support.

FIG. 1D is an exploded perspective view of the heater and the lifting mechanism of an embodiment.

FIG. 1E is a perspective view of the heater and the shaft extending downward from the center of the heater.

FIG. 2A is a side view of an upper pin portion of a support pin.

FIG. 2B is a detailed view of the connector of the upper pin portion shown in FIG. 2A.

FIG. 2C is a side view of the upper pin portion shown in FIG. 2A, rotated 90 degrees.

FIG. 3A is a perspective view of a lower pin portion of a support pin.

FIG. 3B is a perspective view of the lower pin portion shown in FIG. 3A, rotated 90 degrees.

FIG. 3C is a side view of the lower pin portion shown in FIG. 3A.

### DETAILED DESCRIPTION OF THE PREFERRED EMBODIMENT

The following detailed description of the preferred embodiments and methods presents a description of certain specific embodiments to assist in understanding the claims. However, one may practice the present invention in a multitude of different embodiments and methods as defined and covered by the claims. For example, while the quick-release connection mechanism of the preferred embodiment is a bayonet mechanism, the skilled artisan will appreciate that other quick-release mechanisms can be hand-operated, without threaded screws or bolts.

Referring more specifically to the drawings for illustrative purposes, the present invention is embodied in the devices generally shown in the Figures. It will be appreciated that the apparatuses may vary as to configuration and as to details of the parts, and that the methods may vary as to the specific steps and sequence, without departing from the basic concepts as disclosed herein.

In an ALD process, gas delivery is used to keep reactants separate. The reactants in ALD are not mixed as in CVD reactions. Furthermore, in ALD chambers, controls for delivering reactants are programmed for alternate and sequential pulses with removal or purge steps therebetween. Temperatures are typically maintained between 100° C. and 500° C., depending upon the reactants, to ensure self-saturating adsorption and reactions, such that less than about one molecular monolayer is deposited per cycle.

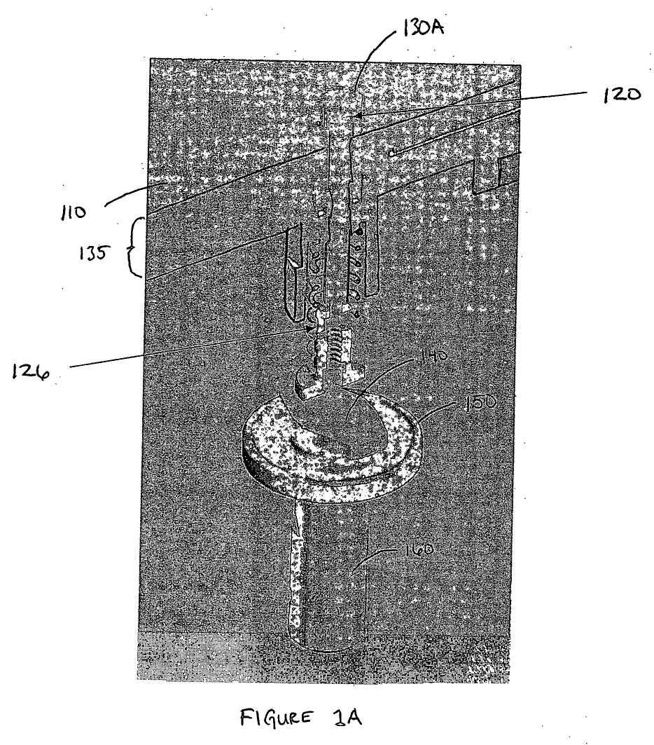

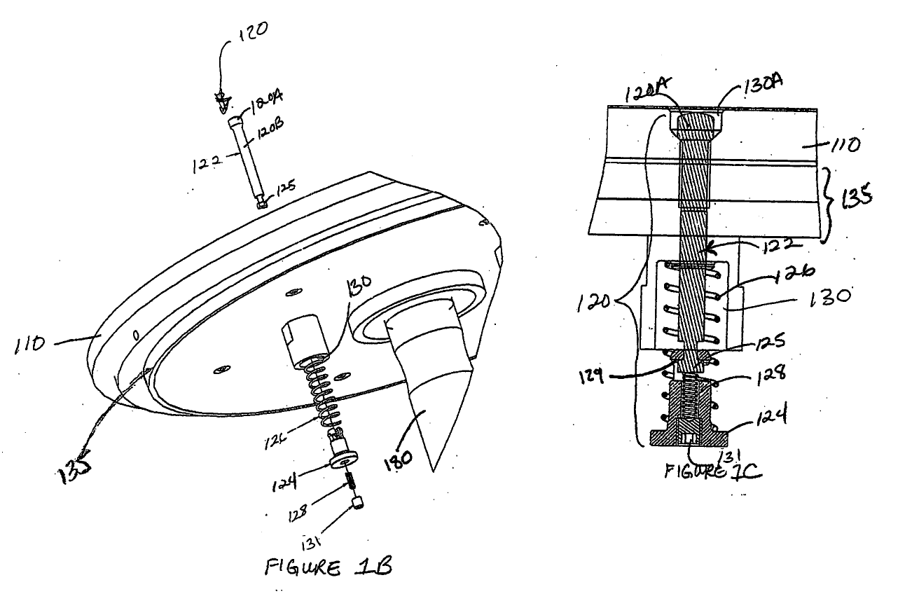

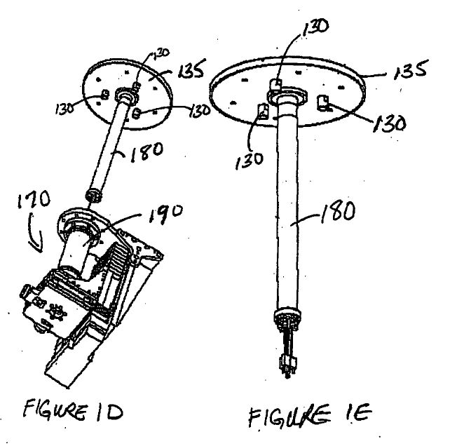

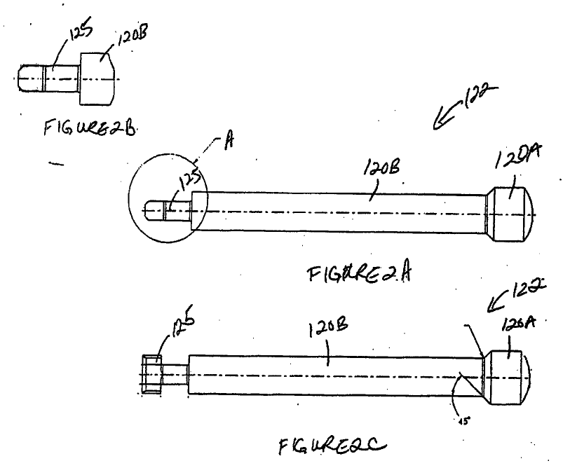

An embodiment is shown in FIGS. 1A-1C. As shown in FIG. 1A, a substrate support (e.g., a susceptor or a chuck) 110 is configured to support a substrate (not shown) thereon. The substrate support 110 preferably has at least three support structures or pins 120 slidably mounted in support pin openings or bores 130 in the substrate support 110. It is generally desirable to minimize the number of support pins 120 to minimize the mechanical complexity of the substrate support 110. In a preferred embodiment, the substrate support 110 has three support pins 120, each positioned 120 degrees apart in the radial direction around the substrate support 110 (see FIGS. 1D and 1E). The skilled artisan will understand that the support pins 120 may be positioned either near the center of the substrate support 110 or closer to the edge. In the illustrated embodiment shown in FIGS. 1D and 1E, the support pins 120 are positioned approximately midway between the center and the edge of the substrate support 110. The support pins 120 define a planar support platform for the substrate to space the substrate above the substrate support 110. In a preferred embodiment, the substrate support 110 is formed of titanium. In alternative embodiments, the substrate support 110 may be formed of stainless steel, aluminum, silicon, alumina (ceramic), nickel, nickel alloys (e.g., Inconel®, Hastelloy®), etc.

In the illustrated embodiment, the substrate support 110 is mounted over a heater 135. The heater 135 is connected to a shaft 180 (see FIGS. 1D and 1E) in the center of the substrate support 110. The shaft 180 is driven up and down by a lead screw that is motor driven, which will be described in more detail below. As shown in FIGS. 1A-1C, the openings 130 extend through both the substrate support 110 and the heater 135.

By using the support pins 120 to raise the substrate above the top surface of the substrate support 110 during loading and unloading, a robot or wafer handling arm does not contact the top surface of the substrate support 110, thereby minimizing the likelihood of damage to the substrate and the substrate support 110. The skilled artisan will appreciate that support pins 120 allow the use of transport forks and paddles to reach under the substrate loading or unloading the substrate. The use of support pins 120 for substrate loading/unloading also prevents the problems of stick and slide, where the substrate could be difficult to pick up due to suction and where the substrate could slide on trapped gas during drop off.

As shown in FIG. 1A, an oblong connector 140 is positioned under the heater 135 and the support pins 120. The oblong connector 140, is connected, preferably threaded, to a base 160, which is secured to the floor of the processing chamber. The substrate support 110 is moved up and down by a lifting mechanism 170 (see FIG. 1D), such as, for example, a motor or an air cylinder, for electrically or pneumatically driving the substrate support 110 up and down. In a preferred embodiment, the lifting mechanism 170 is driven by a lead screw connected to an electric motor. The skilled artisan will understand that, in certain embodiments, the lifting mechanism is driven by a pneumatic actuator.

As shown in the exploded perspective view of FIG. 1B and the cross-sectional side view of FIG. 1C, the substrate support 110 has aligned support pin openings or bores 130 extending through the substrate support 110 from the top surface of the support 110 through to the bottom surface of the heater 135. Each of the openings 130 preferably has a diameter of from about 6 mm to about 10 mm. A support pin 120 is slidably mounted in each of the openings 130 and configured to raise and/or lower a substrate. As shown in FIG. 1C, each of the support pins 120 is positioned to slide within an opening 130. When the substrate is loaded onto or unloaded from the substrate support 110, the slidably mounted support pins 120 rise through the openings 130 in the substrate support 110 and raise or lower the substrate, as will be described in more detail below.

Each support pin 120 preferably has a pin head 120A with a substantially cylindrical surface that, when lowered, is seated in a recess 130A in the upper part of the substrate support 110, as best seen in FIG. 1C. The pin head 120A preferably has a diameter larger than the diameter of the body 120B of the support pin 120. The diameter of the body 120B of the support pin 120 is preferably slightly smaller than the diameter of the opening 130 such that the support pin 120 may slide within the opening 130 without causing abrasion that may result from contact with the inner walls of the opening 130. The support pins 120 may be raised and/or lowered, relative to the substrate support 110, to raise and/or lower a substrate.

In the embodiment shown in FIGS. 1A-1C, 2A and 2C, the support pins 120 have pin heads 120A that are slightly tapered (gradually lessening in width toward the pin shaft or body 120B). As shown in FIG. 1C, the recess or opening 130A in the substrate support 110 into which the pin head 120A is withdrawn when “lowered” is also tapered. In the illustrated embodiment, as the recess 130A is tapered and the mating surface of the pin head 120A is also tapered, the mating surface of the pin head 120A mates with the surface of the recess 130A to inhibit gas flow through the openings 130. The skilled artisan will appreciate that inhibition of gas flow through the openings minimizes the risk of backside contamination of the substrate.

The skilled artisan will appreciate that the support pin heads 120 may be formed with a tapered surface that mates with a correspondingly shaped tapered surface of the recesses 130A in the lowered position, as shown in the illustrated embodiment. Alternatively, the recesses 130A may be formed with a surface that mates with a cylindrical pin head 120A.

As shown in FIGS. 1B and 1C, each support pin 120 includes an upper pin 122 and a lower pin 124, which engage, preferably by means of a bayonet mount. The upper and lower pins 122, 124 preferably engage and lock together when the upper and lower pins 122, 124 are rotated with respect to one another by a technician, preferably by less than about 360 degrees and a spring force from a compressed spring mechanism 128, e.g., a compression spring, biases the upper and lower pins 122, 124 apart. Preferably, the rotation is less than 180 degrees, and in the illustrated embodiment is about 90 degrees.

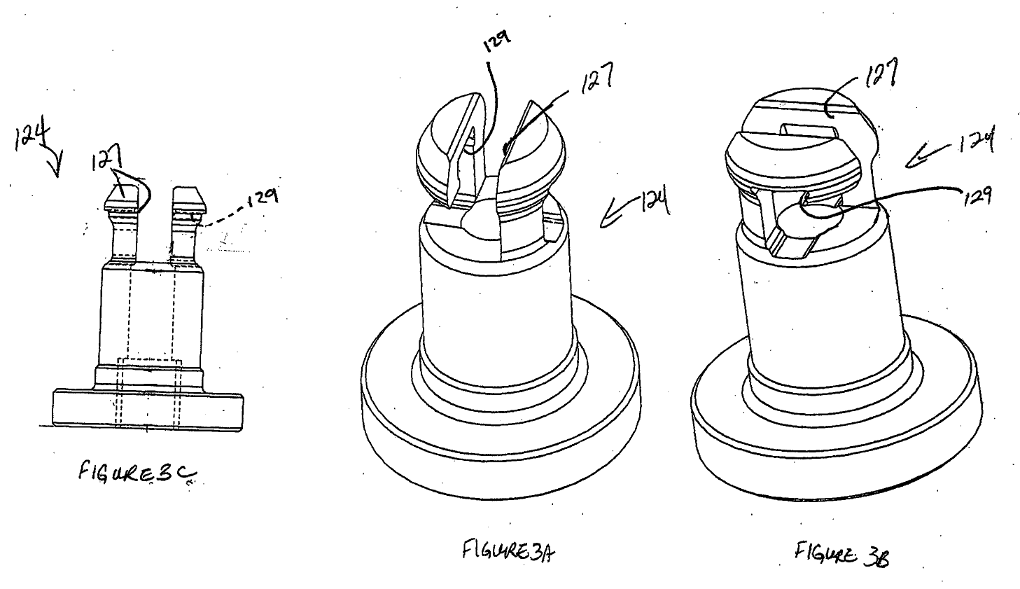

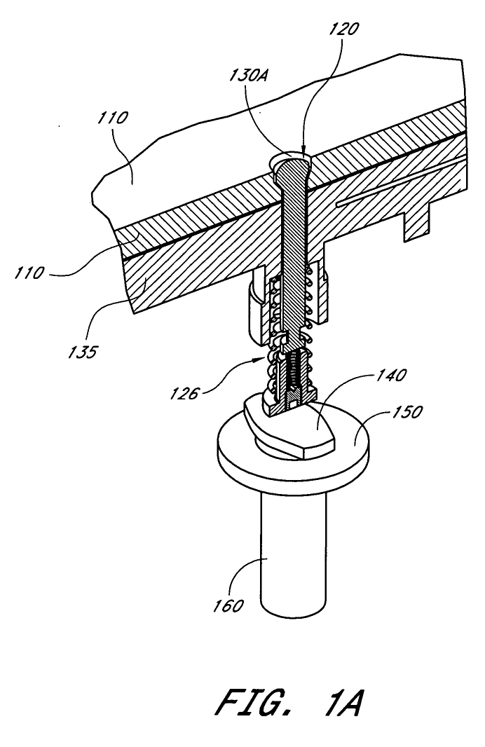

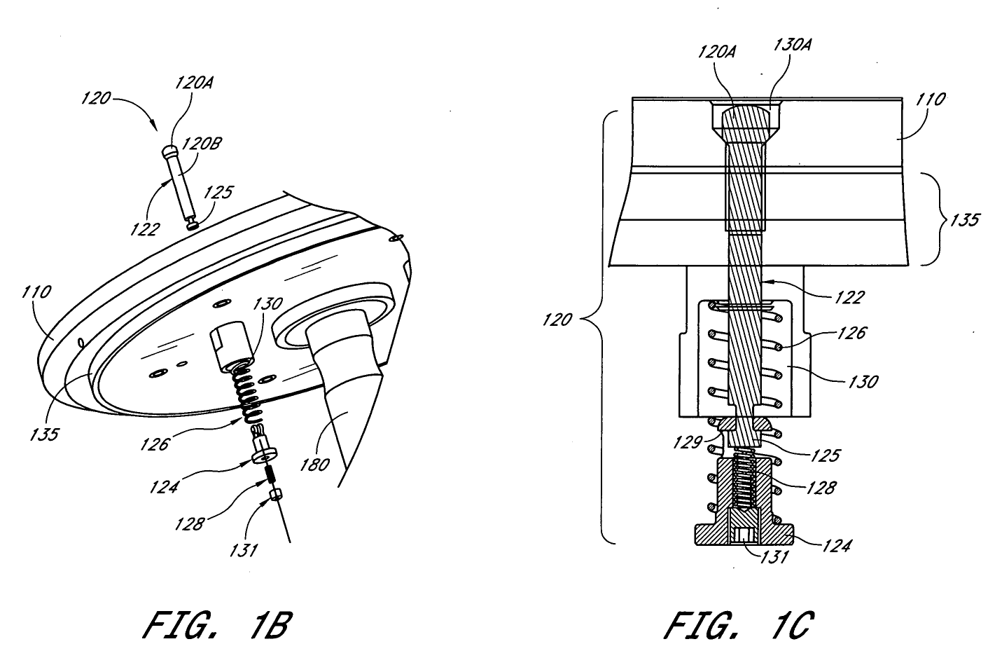

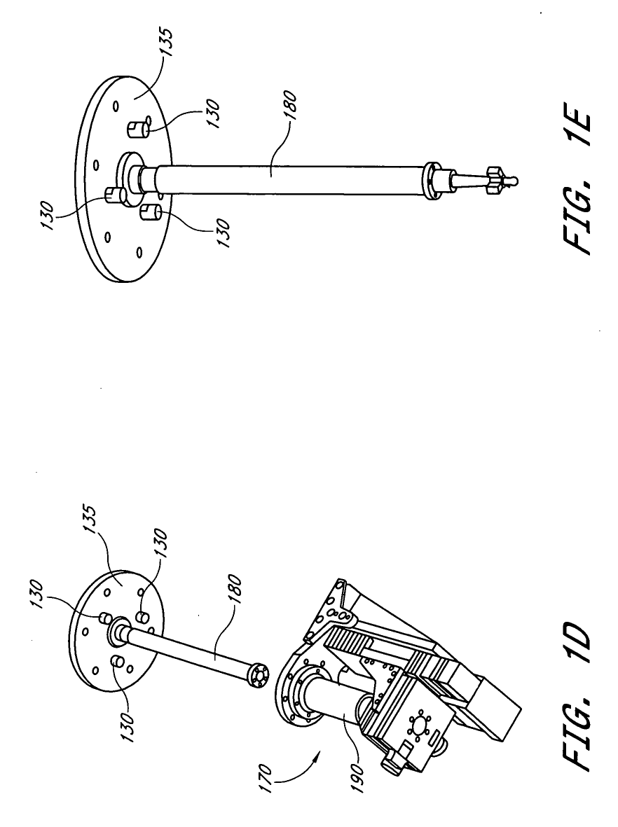

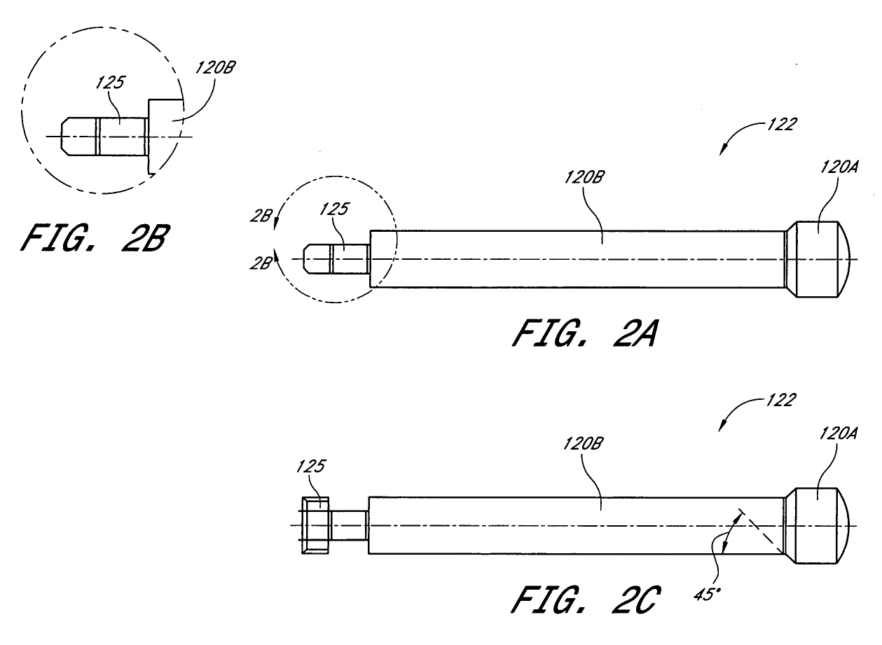

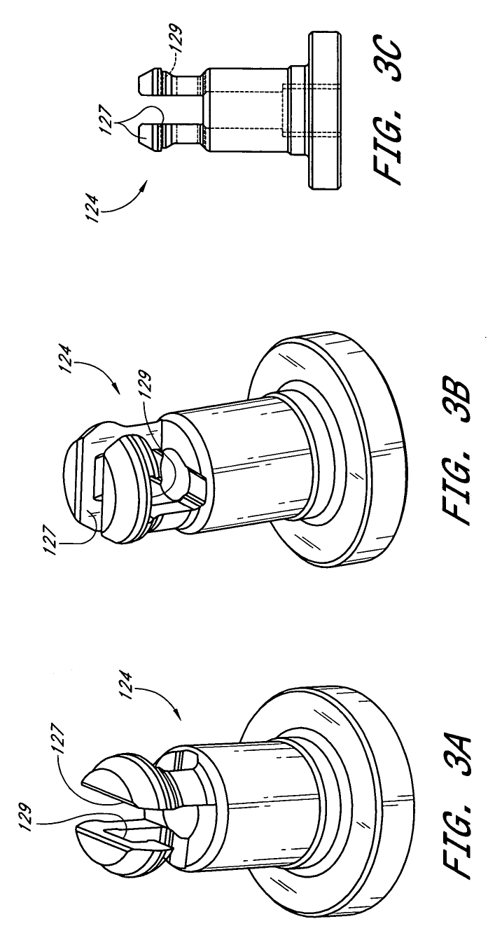

FIG. 2A is a side view of the upper pin 122 and FIG. 2C is a side view of the upper pin shown in FIG. 2A, rotated 90 degrees. As shown in FIGS. 2A-2C, the upper pin 122 has a connector 125, which is configured to engage with a slot 127 and groove 129 in the lower pin 124 (see FIGS. 3A and 3B). FIG. 2B is a detailed view of the connector 125 in circle A in FIG. 2A.

FIG. 3A and FIG. 3B are perspective views of the lower pin 124, with FIG. 3B being a perspective view rotated about 90 degrees from the perspective view of FIG. 3A. FIG. 3C is a side view of the lower pin 124. The skilled artisan will understand that when either the upper pin 122 or the lower pin 124 is rotated preferably by about 90 degrees after the connector 125 is inserted into the slot 127 (by pushing the upper and lower pins 122, 124 and compressing the spring 128), the upper pin 122 is biased away from the lower pin 124. After rotation by about 90 degrees, the connector 125 is biased by the spring 128 to rest against the supper surface of a groove 129 on the lower pin 124. The compression spring 128 keeps the upper pin 122 and lower pin 124 locked in place (see FIG. 1C). In this rotated position, the upper pin 122 cannot become disengaged from the lower pin 124 unless it is pushed down against the resistance of the spring 128 out of the groove 129 and rotated back 90 degrees to release the spring 128. The skilled artisan will understand that, in this embodiment, no tools are necessary to join the upper and lower pins 122, 124 and that the quick-release mechanism (bayonet mount) and spring 128 eliminate the need for a threaded interface between the upper and lower pins 122, 124, thereby minimizing undesirable particle generation and greatly simplifying installation and replacement.

The upper pin 122 preferably has an enlarged head 120A, as shown in FIGS. 1A-1C and 2A and 2C, and is preferably formed of an amorphous polymer PBI (polybenzimidazole) material, such as Celazole®, which is a trademark of PBI Performance Products, Inc. of Charlotte, N.C., U.S.A. and commercially available from Quadrant Engineering Plastic Products of Reading, Pa., U.S.A. The PBI material is desirable because it has high temperature resistance. An upper pin 122 formed of a PBI material provides a non-metallic pin head 120A, which prevents metal contamination from the pin head 120A on the backside of the substrate. The PBI pin heads 120A also eliminate the need for an alumina passivation layer. The lower pin 124 is also preferably formed of a PBI material. Alternative non-metallic materials for the lower pin 124, include, but are not limited to, ceramics (e.g., alumina) and engineering plastics, such as Torlon, Semitron, Peek, Ultem, Vespel, and Ertalyte). The lower pin can also be a metal such as titanium or stainless steel.

In the illustrated embodiment, the lower pin 124 is configured to engage with the compression spring 128, as shown in FIGS. 1B and 1C. An attachment means 131, such as a set screw in the illustrated embodiment, is provided to secure the compression spring 128 in place in the lower pin 124 prior to installment. As shown in FIG. 1C, the compression spring 128 fits into a center bore of the lower pin 124.

As noted above, the support pins 120 are configured to rise above the top surface of the substrate support 110 and to be seated within the recesses 130A when the substrate support 110 is driven down and up, respectively, controlled by the lifting mechanism 170. As discussed above, the lifting mechanism 170, such as, for example, a motor or an air cylinder, electrically or pneumatically drives the substrate support 110 up and down. In a preferred embodiment, the lifting mechanism 170 is driven by a lead screw connected to an electric motor. The skilled artisan will understand that, in certain embodiments, the lifting mechanism is driven by a pneumatic actuator.

As shown in FIG. 1A, in a preferred embodiment, the oblong connector 140 remains stationary relative to the chamber. A jam nut 150 (for adjusting and tightening the connection between the oblong connector 140 and the base 160) is positioned between the oblong connector 140 and the base 160. To lower the support pins 120 from a “raised” position above the top surface of the substrate support 110, the lifting mechanism 170 drives the substrate support 110 up. Initially, as the substrate support 110 moves upward, the spring 126 biases the support pins 120 (which remain stationary relative to the platform or connector 140) to be retracted or “lowered” into the recesses 130A of the substrate support 110. The pin head 120A sits in the countersunk recesses 130A and cannot lower further with respect to the support 110, while sealing the bore 130 from reactant gases. With continued upward movement of the support 110 to seal the chamber, the pins 120 move with the support 110.

To raise the support pins 120 from a “lowered” position seated in the recesses 130A, the substrate support 110 is driven downward by the lifting mechanism 170 shown in FIG. 1D. Initially the support pins 120 (biased in the retracted position by the spring 126) move downwardly with the substrate support 110 as the chamber is opened. Continued downward movement causes the bottom surface of each of the support pins 120 to contact the oblong connector 140. The contact of the support pin 120 with the oblong connector compresses the spring 126 surrounding the lower portion of the support pin 120, as shown in FIGS. 1A-1C. As the spring 126 is compressed while the substrate support 110 is driven downward by the lifting mechanism 170, the spring 126 attains a restoring force that will facilitate relative “lowering” of the pin 120 when the substrate support 110 is lifted next time. Accordingly, the combination of the spring 126 and the platform or “floor” for downward pin movement provided by the oblong connector 140 permits the pins to move relative to the substrate support 110 while the substrate support 110 moves up and down, without requiring the pins to be fixed relative to the platform formed by the connector 140, and also allowing the use of shorter pins 120. Fixture of the pins 120 would prevent lateral play of the pins 120 relative to the chamber and risk breakage of the pins in the case of any lateral movement of the substrate support 110 during loading and unloading. With the illustrated arrangement, the pins 120 will move laterally with any such small lateral movements of the substrate support 110.

FIG. 1D is an exploded perspective view of the heater 135 and the lifting mechanism 170. FIG. 1E is a perspective view of the heater 135 and the shaft 180 extending downward from the center of the heater 135. As shown in FIG. 1D, the heater 135 is mounted to the lifting mechanism 170. In the illustrated embodiment, the shaft 180 fits inside the bellows assembly 190 of the lifting mechanism 170 and mounts to the lifting mechanism 170 at the inside base of the bellows assembly 190. The lifting mechanism 170 is preferably secured to the bottom floor of the processing chamber. The skilled artisan will understand that the bellows assembly 190 creates a seal at the bottom of the processing chamber.

When the support pins 120 are lowered, the support pins 120 are withdrawn so that pin heads 120A of the support pins 120 are seated in the recesses 130A of the support pin openings 130 and the top surfaces of the support pins 120 are slightly recessed in (or in other embodiments, flush with) the top surface of the substrate support 110 on which the substrate is mounted so that the substrate rests on the substrate support 110.

FIG. 1C illustrates a support pin 120 withdrawn into a recess 130A. Preferably, the support pin heads 120A seat snugly in the recesses 130A and form a seal so that reactant gases cannot flow into and through the openings or bores 130 where they could be trapped and contaminate the backside of the substrate, or diffuse out and mix with other reactants to contaminate the wafer with CVD-generated particles and non-uniformity. Each support pin head 120A preferably mates with the surface of the corresponding recess 130A of the opening 130 so as to inhibit gas flow through the opening 130 in the substrate support 110 during processing of the substrate to prevent contamination of the substrate backside. Furthermore, in some embodiments, a flush top surface on the substrate support 110 provides a uniform substrate support surface (e.g., uniformly heated) for uniform processing of the substrate. It will be understood that the support pins 120 are typically in the “lowered” position during processing of the substrate. The additional spring 126 pulls the pin head 120A against the lower surfaces of the recess 130A in the substrate support 110 to provide a seal when the support pin 120 is in the lowered position relative to the support 110.

The support pin head 120A design shown in FIG. 1C and the corresponding countersunk recesses 130A also provide a stopping point for the support pins 120 when they are lowered so that they may be predictably lowered to the correct position in the substrate support 110, where the tops of the pin heads 120A are flush with the upper surface of the substrate support 110. The support pins 120, when lowered, thus provide the substrate support 110 with a predictably flush upper surface that would heat a substrate uniformly, as discussed above.

In a “raised position” the support pins 120 preferably space a substrate above the upper surface of the substrate support 110 in a range of about 0.100 to about 1.0 inch, and more preferably in a range of about 0.2 to about 0.8 inch, and even more preferably at a height of about 0.60 inch (15 mm) from the top surface of the substrate support 110.

In the illustrated embodiment, the substrate support 110 is heated by, for example, a resistive heater 135 below the substrate support 110. In other embodiments, the substrate holder 110 can be radiantly heated by radiant heaters mounted outside the reaction chamber. In such radiantly heated embodiments, a plurality of radiant heat lamps is preferably arranged around the outside of the reaction chamber for heating the substrate and catalyzing the chemical deposition on the substrate. In some embodiments, an upper bank of elongated heat lamps may be arranged outside of an upper wall of the reaction chamber and a lower bank of heat lamps may be arranged cross-wise to the upper bank of lamps. In other embodiments, a concentrated array of heat lamps may be directed upward from underneath the substrate support 110. Such lamp arrangements are employed in CVD chambers commercially available from ASM America, Inc. of Phoenix, Ariz. under the trade name EPSILON®.

In some embodiments, the substrate support 110 is capable of rotation for rotating the substrate during processing of the substrate. The rotation of the substrate support 110 is preferably actuated by a rotary drive attached to a rotating shaft extending from the substrate support 110 and heater 135. The skilled artisan will appreciated that rotation of the substrate during processing can help to ensure uniformity of heating and distribution of reactant gases, thereby increasing the uniformity of the processed substrate.

It will be understood that the embodiment described herein can be easily assembled using the quick-release mechanism for the pins. A technician assembles the substrate support 110 and support pin 120 device by inserting the upper pin 122 into the lower pin and rotating after placing the substrate support 110 into the chamber. The skilled artisan will appreciate that tools are not necessary to assemble the support pins 120 in the substrate support 110. Elimination of tools in the assembly process reduces the amount of particles caused by galling of the support pins 120 and openings 130. Furthermore, the pin heads 120A in the illustrated embodiment prevents metal contact on the substrate, and seals potential trap locations of the openings 130.

Although this invention has been disclosed in the context of certain preferred embodiments and examples, it will be understood by those skilled in the art that the present invention extends beyond the specifically disclosed embodiments to other alternative embodiments and/or uses of the invention and obvious modification thereof. Thus, it is intended that the scope of the present invention herein disclosed should not be limited by the particular disclosed embodiments described above, but should be determined only by a fair reading of the claims that follow.

1. A substrate support for processing semiconductor substrates, the substrate support having a plurality of openings extending from a top surface to a bottom surface, the substrate support comprising:
a plurality of support pins, wherein each of the plurality of support pins is slidably mounted in one of the plurality of openings, each of the plurality of support pins comprising:
an upper pin; and
a lower pin, wherein the upper pin is engaged with the lower pin by means of a bayonet mount.

2. The substrate support of claim 1, wherein each of the plurality of support pins is formed of a non-metal material.

3. The substrate support of claim 2, wherein the non-metal material is polybenzimidazole.

4. The substrate support of claim 2, wherein the non-metal material is a ceramic.

5. The substrate support of claim 1, further comprising a lifting mechanism configured to raise or lower the substrate support.

6. The substrate support of claim 5, wherein the lifting mechanism is driven by an electric motor.

7. The substrate support of claim 5, wherein the lifting mechanism is driven by a pneumatic cylinder.

8. The substrate support of claim 5, wherein the support pins are configured to move vertically relative to the substrate support when the substrate support is raised or lowered.

9. The substrate support of claim 8, configured such that when the substrate support is lowered, the upper pin of each of the plurality of support pins rises above the top surface of the substrate support.

10. The substrate support of claim 8, configured such that when the substrate support is raised, the upper pin of each of the plurality of support pins is withdrawn into one of the plurality of openings.

11. The substrate support of claim 10, further comprising a spring configured to bias the support pins downwardly relative to the substrate support.

12. The substrate support of claim 1, wherein the substrate support is mounted over a heater.

13. The substrate support of claim 1, wherein the substrate support is positioned in a chamber and the substrate support further comprises a connector under the heater, wherein the connector is connected to a base secured to a floor of the chamber.

14. The substrate support of claim 13, wherein the connector and the base are connected by a jam nut.

15. The substrate support of claim 1, further comprising a radiant heater configured to heat the substrate support.

16. The substrate support of claim 1, wherein each of the plurality of support pins comprises a pin head configured to be seated within an opening of the substrate support such that a top surface of the pin head is below the top surface of the substrate support.

17. The substrate support of claim 1, wherein each of the plurality of support pins comprises an enlarged pin head configured to be seated within an opening of the substrate support such that a top surface of the pin head is substantially flush with the top surface of the substrate support.

18. The substrate support of claim 1, wherein each of the plurality of support pins comprises a pin head configured to be above the top surface of the substrate support while a substrate is lifted off or dropped onto the top surface of the substrate support.

19. The substrate support of claim 1, further comprising a spring and a connector on a lower surface of the upper pin, wherein the spring is configured to bias the connector against and engage a groove in the lower pin to resist rotation of the upper pin relative to the lower pin.

20. The substrate support of claim 19, wherein the upper and lower pins are configured to be rotated by less than 180 degrees relative to each other for engagement.

21. The substrate support of claim 19, wherein the upper and lower pins are configured to be rotated by less than 360 degrees relative to each other for engagement.

22-36. (canceled)

37. A process tool for processing semiconductor substrate, comprising:
a susceptor having a plurality of openings extending from a top surface to a bottom surface, the susceptor comprising a plurality of support pins, wherein each of the plurality of support pins is slidably mounted in one of the plurality of openings, each of the plurality of support pins comprising an upper pin and a lower pin, wherein the upper pin is engaged with the lower pin by means of a quick-release mechanism;
a lifting mechanism configured to raise or lower the susceptor; and
a heater, wherein the substrate support is mounted over the heater.

38. The process tool of claim 37, wherein the process tool is configured for atomic layer deposition.

39. The process tool of claim 37, wherein each of the plurality of support pins is formed of a non-metal material.

40. The process tool of claim 39, wherein the non-metal material is polybenzimidazole.

41. The process tool of claim 39, wherein the non-metal material is a ceramic.

42. The process tool of claim 39, wherein the lifting mechanism is driven by an electric motor.

43. The process tool of claim 37, wherein the lifting mechanism is driven by a pneumatic cylinder.

44. The process tool of claim 37, wherein the support pins are configured to move vertically relative to the substrate support when the susceptor is raised or lowered.

45. The process tool of claim 37, wherein the susceptor further comprises a lower platform and a spring configured to move vertically relative to the substrate support while the susceptor is raised or lowered.

46. The process tool of claim 37, wherein the susceptor is positioned in a chamber and the susceptor further comprises a connector under the heater, wherein the connector is connected to a base secured to a floor of the chamber.

47. The process tool of claim 46, wherein the connector and the base are connected by a jam nut.

48. The process tool of claim 37, wherein each of the plurality of support pins comprises a pin head configured to be seated within an opening such that a top surface of the pin head is substantially flush with the top surface of the substrate support.

49. The process tool of claim 37, wherein each of the plurality of support pins comprises a pin head configured to be above the top surface of the substrate support while a substrate is lifted off or dropped onto the top surface of the substrate support.

50. The process tool of claim 37, wherein the quick-release mechanism comprises a bayonet mount.

51. The process tool of claim 50, wherein each of the support pins further comprises a spring and a connector on a lower surface of the upper pin, wherein the spring is configured to bias the connector against and engage a groove in the lower pin to resist rotation of the upper pin relative to the lower pin.

52. The process tool of claim 51, wherein the upper and lower pins are configured to be rotated by less than 180 degrees relative to each other for engagement.

53. The process tool of claim 51, wherein the upper and lower pins are configured to be rotated by less than 360 degrees relative to each other for engagement.

54. A wafer support pin configured for slidably mounting in an opening in a wafer support for semiconductor processing, the support pin comprising:
an upper pin having an enlarged pin head and an upper pin shaft extending downwardly from the pin head; and
a lower pin configured to engage the upper pin by means of a bayonet mount.
